(19) United States
(12) Patent Application Publication
(10) Pub. No.: US 2007/0106964 A1
(43) Pub. Date: May 10, 2007

(54) Optimized microchip and related methods

(76) Inventors: James D. Meindl, Marietta, GA (US); Deepak C. Sekar, Atlanta, GA (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 11/445,026

(22) Filed: Jun. 1, 2006

Related U.S. Application Data
(60) Provisional application No. 60/736,075, filed on Nov. 10, 2005.

(51) Int. Cl. G06F 17/50; H01L 25/00

(52) U.S. Cl. 716/2; 326/101; 716/8

(57) ABSTRACT

Various embodiments of an optimized microchip and methods of fabricating and operating the same are provided. One microchip embodiment, among others, comprises a repeater-type transistor located in a first path corresponding to a first path type, the repeater-type transistor having a parameter at a first design value, and a logic-type transistor located in the first path or a different path, each of the paths corresponding to the first path type, the logic-type transistor having the parameter at a second design value.

### CROSS-REFERENCE TO RELATED APPLICATION

This application claims priority to copending U.S. provisional application entitled, “UNIQUE OPTIMIZATION OF LOGIC AND COMMUNICATION TRANSISTOR TECHNOLOGIES,” having Ser. No. 60/736,075, filed Nov. 10, 2005, which is entirely incorporated herein by reference.

### TECHNICAL FIELD

The present disclosure is generally related to electronics technology and, more particularly, is related to a microchip or integrated circuit technology.

### BACKGROUND

Microchip or integrated circuit technology has undergone significant advances over recent years. For instance, circuit miniaturization has resulted in practical consumer benefits such as pocket-sized cell phones, flat-screen televisions that can be hung on a wall like a picture frame, among a variety of other consumer product advancements. Another advancement is speed. Substantially gone are the days of waiting prolonged periods for a computer boot-up, or connecting a phone call or to the Internet.

FIG. 1 is a schematic diagram of an exemplary microchip 100. As shown, microchips 100 generally include a plurality of transistors responsible for different functions, including memory transistors 102, communication transistors (or repeaters) 104, and logic transistors 106. Thus, memory transistors 102 perform the function of providing storage of data. Memory transistors 102 are thus generally used for cache structures in a microchip, such as a data cache in a microprocessor. Logic transistors 106 are generally used in logic blocks of a chip, and thus logic transistors 106 may be used in an integer execution unit, floating point unit, among others. Repeaters 104 are typically employed to reduce the delay of long wires in a chip, which enables an improvement of speed of data transmission. As is known, a repeater transistor 104 may be embodied as an inverter or as a plurality of inverters (e.g., cascade of inverters). Other types of transistors, not shown, may include I/O transistors and clock transistors. Up until relatively recently (e.g., past 2-3 years), the power consumed by repeaters 104 has been relatively negligible. However, as the demand for speed and miniaturization continues, the power consumed by repeaters has provided increasing concern for future microchips. For instance, recent studies indicate that repeater count increases exponentially with scaling, and could form approximately 70% of the cells in a microprocessor's logic block at the 32 nanometer (nm) node (i.e., width of the smallest wire in a microchip). Such increased area coverage in a chip 100 raises concerns about repeater power dissipation.

A simulation tool called MINDS is used to find the trends for repeater power dissipation with scaling. The n-tier methodology used in MINDS is well-known, and thus discussion of the same is omitted here for brevity. To summarize, MINDS arranges wires in metal levels based on a stochastic wiring distribution and available wire area. The pitch of every orthogonal pair of metal levels is calculated by equating a specified fraction of a clock period to the delay of the longest wire in that pair of metal levels. Logic gates are modeled as two-input NAND gates and are sized based on average wire length estimates. Simulations using MINDS (Multilevel Interconnect Network Design simulator), based on (1) low operating power (LOP) ITRS (International Technology Roadmap for Semiconductors, which conveys the expected threshold voltages in the future) transistor parameters, and (2) suboptimal repeater insertion with a 10% delay penalty and using Rent's constants k and p are 4 and 0.6 respectively, have been shown to match data from industrial designs in previous work. Leakage power models, such as those shown in D. Sylvester, “BAPAC,” www.eecs.umich.edu/˜dennis/bacpac/bacpac_models.HTML have been used. Results from MINDS indicate that while repeaters take up 12% of a low-power combinational logic block's power at 65 nm, they may consume a staggering 53% of the power at 22 nm.

Thus, there is a need to reduce repeater power for high frequency (e.g., in the giga-Hertz, GHz range), short channel length (e.g., 40 nm and lower) microchip architectures (e.g., combinational logic blocks).

### SUMMARY

Embodiments of the present invention provide an optimized microchip and fabrication and operation methods. Briefly described, in architecture, one embodiment of a microchip, among others, comprises a repeater-type transistor located in a first path corresponding to a first path type, the repeater-type transistor having a parameter at a first design value, and a logic-type transistor located in the first path or a different path, each of the paths corresponding to the first path type, the logic-type transistor having the parameter at a second design value.

Embodiments of the present invention can also be viewed as providing methods of fabricating a microchip. In this regard, one embodiment of such a method, among others, can be broadly summarized as providing a repeater-type transistor in a first path corresponding to a first path type on the microchip, the repeater-type transistor having a parameter at a first design value, and providing a logic-type transistor in the first path or a different path on the microchip, each of the paths corresponding to the first path type, the logic-type transistor having the parameter at a second design value.

Embodiments of the present invention can also be viewed as providing methods of operating a microchip. In this regard, one embodiment of such a method, among others, can be broadly summarized as imposing a first design value on a parameter corresponding to a repeater-type transistor located in a path corresponding to a first path type on the microchip, and imposing a second design value on the parameter corresponding to a logic-type transistor located in the same path or a different path corresponding to the first path type on the microchip.

Other systems, methods, features, and advantages will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

Many aspects of the disclosure can be better understood with reference to the following drawings. The components in the drawings are not necessarily to scale, emphasis instead being placed upon clearly illustrating the principles of the present apparatus and method. Moreover, in the drawings, like reference numerals designate corresponding parts throughout the several views.

FIG. 1 is a schematic diagram that illustrates an exemplary microchip.

FIG. 2 is a schematic diagram that illustrates a microchip, in accordance with one embodiment.

FIG. 3 is a schematic diagram that illustrates an embodiment where repeaters connect logic transistors of two separate functional block units.

FIG. 4 is a schematic diagram that illustrates an embodiment where repeaters connect logic transistors within a functional block unit.

FIG. 5 is a simulation plot that illustrates repeated wire energy-delay product (EDP) versus threshold voltage, in accordance with one embodiment.

FIG. 6 is a simulation plot that illustrates that a delay of a repeated wire using the repeater insertion model is fairly insensitive to increase in threshold voltage near the optimal point, in accordance with one embodiment.

FIG. 7 is a simulation plot that illustrates that a delay of a logic path is more sensitive to threshold voltage.

FIG. 8 is a simulation plot that illustrates that increasing gate size within practical values does not compensate for performance losses associated with higher threshold voltages.

FIG. 9 is a block diagram that illustrates an embodiment of a computer system that may be used in the design or fabrication of an optimized microchip, in accordance with one embodiment.

FIG. 10 is a flow diagram that illustrates an embodiment of an optimized microchip fabrication or design method.

FIG. 11 is a flow diagram that illustrates an embodiment of a method of operating an optimized microchip.

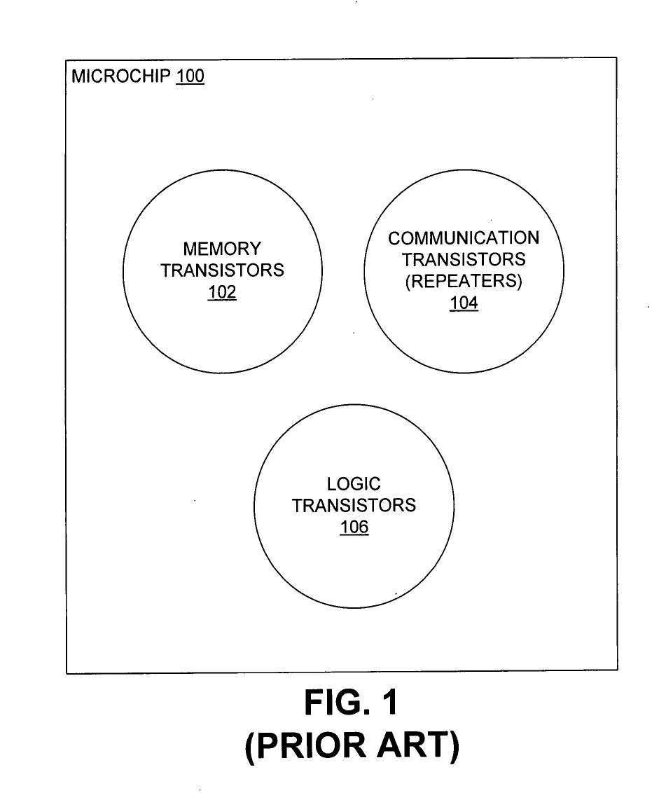

### DETAILED DESCRIPTION

Disclosed herein are various embodiments of an optimized microchip and methods of fabricating and operating the same. One such microchip embodiment comprises a plurality of transistors of various types provided on the microchip. Two of the types of transistors, communication transistors (or repeaters) and logic transistors, operate at different design values for one or more of the same parameters. Parameters may include threshold voltage, channel length, gate dielectric thickness, and supply voltage. For instance, repeaters and logic transistors may be disposed on a microchip, with repeaters representing approximately 20% of the total area of the microchip.

Both types of transistors are located in critical paths or both in non-critical paths, with the understanding that the embodiments described herein may be used in systems where one transistor type may be located in a critical path and the other may be located in a non-critical path. A critical path generally refers to a logic path comprising transistors and wires that determines or impacts the performance (e.g., speed) of a microchip. A non-critical path, in contrast, generally refers to a logic path comprising transistors and wires that does not determine or impact performance of the microchip. For instance, transistors in a non-critical path may be made incrementally slower in speed from one design to the next without altering the overall performance of the microchip.

According to one embodiment, the repeaters of a critical path are configured at a first threshold voltage and the logic transistors in the same or a different critical path on the same microchip are configured at a second design voltage. Accordingly, as is explained below, the microchip operates at significantly reduced (e.g., over 33%) power reduction with negligible performance and area overhead.

The optimization involving repeaters and logic transistors occurs in the context of a technological environment that only fairly recently has seen indications of potentially significant performance penalties due to repeater power consumption as miniaturization progresses. Thus, in the past, the requisite mask investment and perceived wire penalties in such an optimization would likely have generated little, if any, interest from an investment point of view.

Further, optimization in such parameters as threshold voltage results in a negligible performance penalty when compared to other transistors. For instance, memory transistor performance (e.g., speed performance) has a strong correlation to threshold voltage. For instance, increasing threshold voltage for memory transistors is typically either avoided or comes at a cost of higher supply voltages to offset the performance penalty. Similarly, performance is degraded in logic transistors with increases in threshold voltages unless voltage supply is increased. In contrast, repeater performance is relatively immune to changes in threshold voltages, allowing increases with no concomitant change in supply voltages, or even with decreased supply voltages.

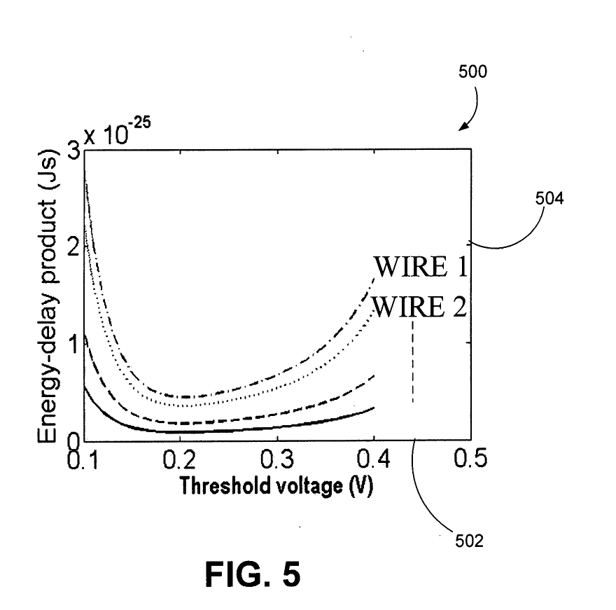

Also, the authors of this disclosure have discovered that an optimal threshold voltage exists for all repeaters of a certain path type in a microchip that minimizes the energy-delay product (EDP) of wires, as shown and explained in conjunction with FIG. 5 below. Accordingly, a designer may use one threshold voltage for all repeaters of a certain path type in a microchip, resulting in minimized masking steps.

In comparison to conventional systems, such change in parameters are implemented when repeaters and logic transistors are disposed along the same path types. For instance, repeaters disposed along critical paths on a microchip may operate under a different threshold voltage than logic transistors disposed along the same or different critical path on the same microchip.

The preferred embodiments that follow are described in the context of a complementary metal-oxide semiconductor (CMOS) microchip or integrated circuit comprising logic transistors and repeaters designed and operated using different threshold voltages in the same path type (e.g., either both in critical paths or both in non-critical paths). It would be understood by those having ordinary skill in the art that other chip technologies may similarly apply, and that other parameters in addition to or in lieu of threshold voltages may be changed.

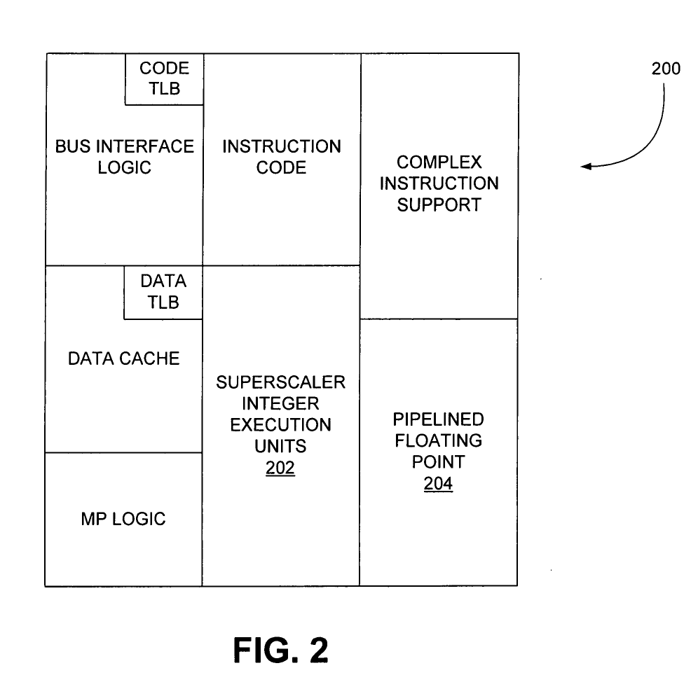

FIG. 2 is a block diagram that illustrates one embodiment of a microchip 200. The microchip 200 may be fabricated from any one of several technologies, including CMOS. The microchip 200 comprises a plurality of transistors of various functional types, the various functional types used in different functional block units (e.g., comprising one or more logic blocks) of the microchip. Such exemplary functional block units are shown in FIG. 2 as including a code translation lookaside buffer (TLB), data TLB, bus interface logic, data cache, microprocessor (MP) logic, instruction decode, superscalar integer execution units 202, complex instruction support, and pipelined floating point 204. The functions implemented by each of these functional block units are well-known and thus discussion of the same is omitted for brevity. Repeaters may be found in each area to connect various transistors within each functional block and/or to connect transistors of different functional block units.

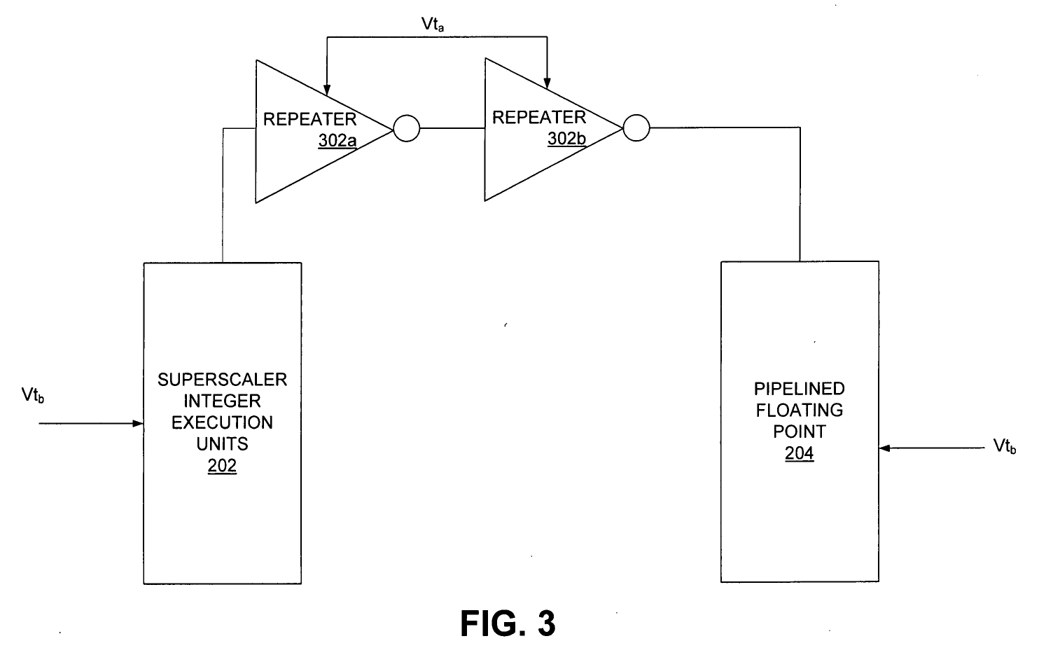

For instance, referring to FIG. 3, shown are two functional block units from the microchip 200 shown in FIG. 2, in accordance with one embodiment. The superscalar integer execution unit 202 comprises logic transistors (not shown) coupled to logic transistors (not shown) of the pipelined floating point unit 204 through two repeaters 302a and 302b. Though represented using high-level inverter symbols, one skilled in the art would understand that the repeaters 302a and 302b may be embodied as a transistor in an inverter configuration. Also, as would be understood by one having ordinary skill in the art, a repeater may be embodied as an inverter or as a plurality of inverters (e.g., cascade of inverters, such as two or more inverters placed back-to-back). In some embodiments, repeater functionality may be embodied in more complex circuitry. Repeater functionality generally refers to a mechanism to reduce signal delay associated with the use of long wires or other conductors. Further, although two repeaters 302a and 302b are shown, fewer or greater numbers of repeaters may be used to couple logic transistors of the two logic blocks 202 and 204. The repeaters 302a and 302b are each symbolically represented as having a first design value, Vₜₐ, of a parameter such as threshold voltage imposed upon each repeater 302a and 302b, whereas the logic blocks are each represented as having imposed upon each of the logic transistors a second design value, V_{tb}, for threshold voltage. As would be understood by one having ordinary skill in the art, logic transistors generally refer to one or more non-repeater transistors used in a logic block of a chip, such as an integer execution unit, floating point unit, among others. In some embodiments, different parameters (e.g., threshold voltage) may be provided for each repeater or logic transistor among (e.g., repeaters 302a and 302b may have different threshold voltages, or repeaters 302a and 302b along one critical path may have different threshold voltages than repeaters found in another critical path). In other words, various combinations within a microchip are possible and thus within the scope of the preferred embodiments, as would be understood by one having ordinary skill in the art.

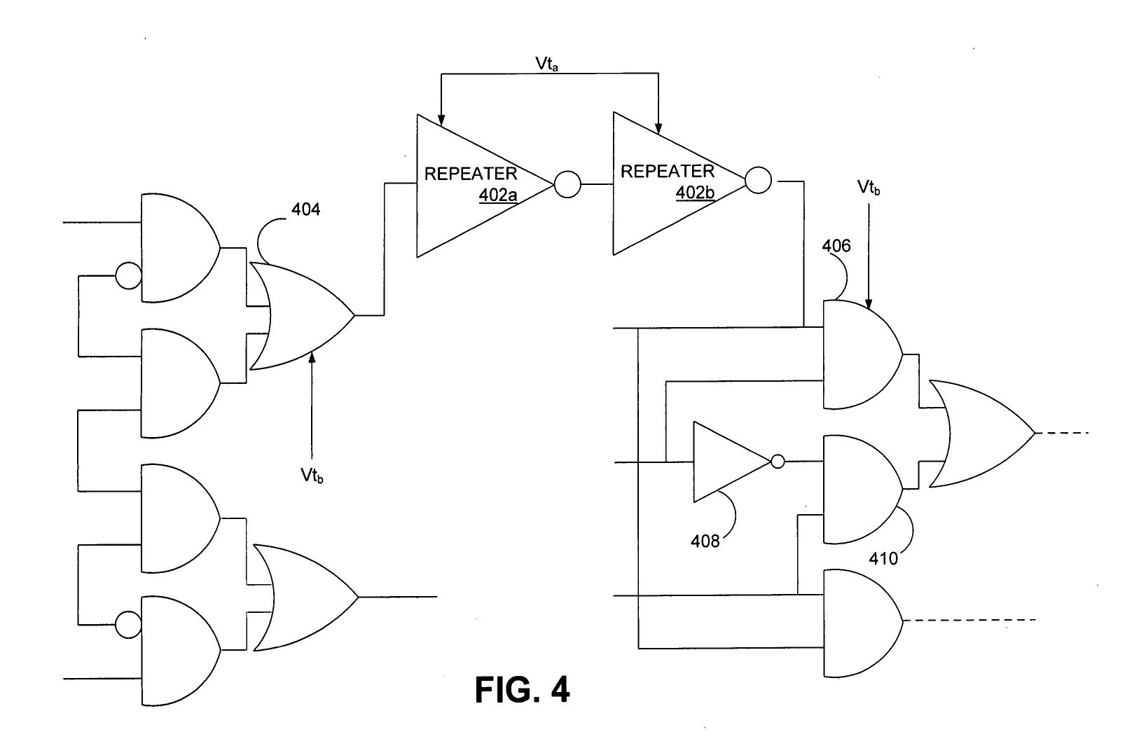

FIG. 4 illustrates another embodiment in which repeaters 402a and 402b connect logic transistors, such as logic transistors 404 and 406 (again, each logic transistor represented using high-level logic gates with the understanding that such logic gates each comprise transistors as is known). The repeaters 402a and 402b are each symbolically represented as having imposed upon each repeater 402a and 402b a first design value, Vₜₐ, for threshold voltage, whereas the logic transistors 404 and 406 are each represented as having a second design value, V_{tb}, for threshold voltage imposed upon the same. It would be appreciated that other parameters may also be varied between the repeaters 402a and 402b (and 302a and 302b of FIG. 3) and the logic transistors 404 and 406 (transistors of separate logic blocks), such as channel length, gate dielectric thickness, and/or supply voltage. Further, in some embodiments, threshold voltage may be the same between repeaters 402a and 402b and logic transistors 404 and 406, with variations found in other parameters.

The following derivation provides a basis to explain why different threshold voltages can be used for logic and repeater transistors. That is, the optimization of a microchip according to an embodiment of the invention is based at least in part on a repeater insertion model, as described below. Although described in the context of threshold voltages, one having ordinary skill in the art would appreciate that the repeater insertion model similarly provides a basis for differences in values of other parameters (e.g., channel length, gate dielectric thickness, etc.) along paths of the same path type. In particular, in implementations where repeater power is a significant fraction of system power, a compact model that minimizes Energy-Delay Product (EDP) of a repeated wire is derived through steps 1-4 below:

$$\begin{matrix}Delay = k [ 0.7 \frac{{R}_{o}}{h} ( \frac{{C}_{int}}{k} + {hC}_{o} ) + \frac{{R}_{int}}{k} ( 0.4 \frac{{C}_{int}}{k} + 0.7 {hC}_{o} ) ] & ( 1 ) \\ Power = ( a \frac{1}{2} {C}_{o} {V}_{dd}^{2} f + {bV}_{dd} {I}_{leak} ) hk + a \frac{1}{2} {C}_{int} {V}_{dd}^{2} f & ( 2 ) \\ Energy - delay product ( EDP ) = {Delay}^{2} Power \\ Set \frac{ⅆ ( EDP )}{ⅆ} = 0 , \\ \frac{ⅆ ( EDP )}{ⅆ} = 0 , simplify \& approximate to get , & ( 3 ) \\ Optimal k = {( 0.73 + 0.7 In {ϕ}_{gate} )}^{2} \sqrt{\frac{{R}_{int} \cdot {C}_{int}}{{R}_{o} \cdot {C}_{o}}} \\ Optimal h = {( 0.88 + 0.7 In {ϕ}_{gate} )}^{2} \sqrt{\frac{{C}_{int} \cdot {R}_{o}}{{R}_{int} \cdot {C}_{o}}} \\ where {ϕ}_{gate} = \frac{\frac{1}{2} {aC}_{o} {V}_{dd}^{2} f}{\frac{1}{2} {aC}_{o} {V}_{dd}^{2} f + {bV}_{dd} {I}_{leak}} & ( 4 )\end{matrix}$$

k=number of repeaters, h=size of repeaters, Rᵢₙₜ=wire resistance, Cᵢₙₜ=wire capacitance, b=percentage of time circuit is not sleep gated, R₀, C₀ & Iₗₑₐₖ=resistance, capacitance & leakage of minimum sized repeater respectively, V_{dd}=supply voltage, a=activity (e.g., percentage of time the circuit is used), and f=frequency. The repeater insertion model described above has been demonstrated to have a relationship between repeater size or repeater number and wire resistance that is within 15% of SPICE simulations when implemented with low operating power ITRS transistor parameters and 1 millimeter (mm) length wire with 100 nanometer (nm) BSIM (i.e., Berkeley MOSFET SPICE model) technology.

Having described a repeater insertion model that provides an underlying basis for microchip optimization described herein, the parameter of threshold voltage is described next. That is, in one embodiment, repeaters have different values of threshold voltage (Vₜ) when compared to logic transistors. One expression for the minimum EDP of a repeater chain can be derived from (3) and (4) above as follows:

$$EDP = {R}_{int} {C}_{int}^{2} [ {R}_{o} ( a \frac{1}{2} {C}_{o} {V}_{dd}^{2} f + {bV}_{dd} {I}_{leak} ) {( \frac{0.7}{δ} + 0.7 γ + \frac{0.4}{γ} + 0.7 δ )}^{2} ( γδ + {ϕ}_{gate} ) ] \\ where γ = {( 0.73 + 0.07 ln {ϕ}_{gate} )}^{2} and \\ δ = {( 0.88 + 0.07 ln {ϕ}_{gate} )}^{2} \qquad ( 5 )$$

The repeated wire EDP vs. Vₜ simulation plot 500 of FIG. 5 indicates that an optimal Vₜ=0.21V exists for all repeated wires (i.e., wires with one or more repeaters contained therein) on a microchip that minimizes their EDP. As shown, the x-axis 502 corresponds to threshold voltage in units of volts and the y-axis 504 corresponds to EDP and is in units of Joules. Such a feature is due to the fact that the wire-independent term inside the square brackets in (5) is minimized to minimize the EDP.

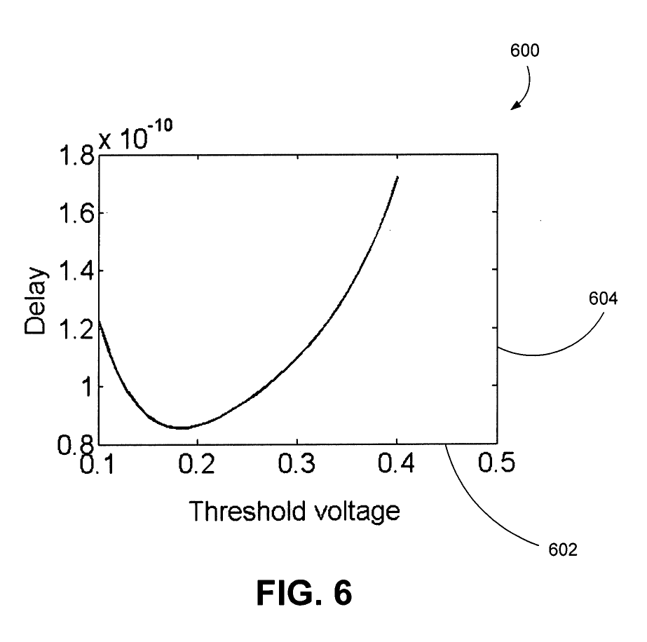

FIG. 6 shows a simulation plot 600 that reveals that the delay of a repeated wire with the repeater insertion model is fairly insensitive to increase in Vₜ near the optimal point. As shown, the x-axis 602 corresponds to threshold voltage (units of volts) and the y-axis 604 corresponds to delay (in units of seconds). Wire 1 represents the plot corresponding to a repeated wire having a higher resistance than wire 2, and so on. Delay increases can be compensated using increased wire sizes. Thus, repeated wires could give the same performance using the repeater insertion model with a Vₜ=0.21V as they give with an ITRS specified Vₜ=0.16V by increasing wire sizes.

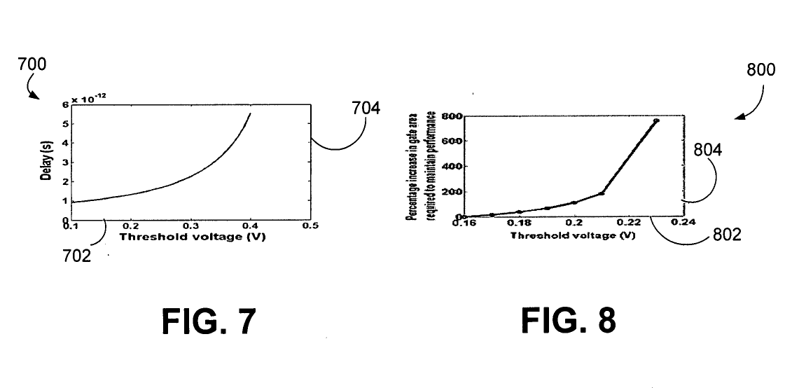

It is well known that the delay of different types of logic paths on a chip is proportional to a Fan-out of 4 (FO4) delay. That is, the delay of an inverter driving four more inverters of the same size through relatively short wires. The delay of a logic path having at least one inverter and relatively short wires is more sensitive to threshold voltage, Vₜ, as shown in the simulation plot 700 of FIG. 7. The x-axis 702 corresponds to threshold voltage (volts) and the y-axis 704 corresponds to delay (normalized to delay at ITRS specified threshold voltage). This feature is largely due to the fact that the output resistance of an inverter, which depends on Vₜ, is much larger than wire resistance. The logic path cannot have its gates sized bigger to maintain performance with higher Vₜ values, because of large die area increases and the need to space a new Vₜ value far enough from the existing Vₜ of 0.16V for manufacturability, as the plot 800 in FIG. 8 shows. The x-axis 802 corresponds to threshold voltage (volts) and the y-axis 804 corresponds to the percentage in gate area required to maintain performance to delay (normalized to delay at ITRS specified threshold voltage).

In light of the simulation plots shown in FIGS. 5-8, it is surmised that repeaters can have higher Vₜ values than logic transistors because repeated wires can achieve their target performance by more power-efficient techniques than through the use of lower Vₜ values, such as wire sizing and optimized repeater insertion. Further optimization may be accomplished by providing repeaters and logic transistors with different (i.e., repeater parameter design value(s) different than the logic transistor parameter design value(s)) channel lengths, gate dielectric thickness and/or supply voltage for logic and communication transistors. Simulation performance analysis based on 1 mm wire at 65 nm (at 500 MHz) and 22 nm (1.4 GHz), described and shown further in the provisional application (Ser. No. 60/736,075), reveal that designs based on the repeater insertion model described herein are more power-efficient than other models for leaky future technologies. Designs based on the repeater insertion model allow increased performance loss with scaling while retaining power efficiency, and such performance loss is compensated for by increasing wire sizes. Further, analysis reveals that use of the repeater insertion model with separate threshold (Vₜ) values for logic and repeater transistors reduces the power of a repeated wire by 53% compared to conventional techniques (e.g., see R. Venkatesan, et al, Trans. VLSI Syst., December 2001), with little to no performance penalty. Also observed is that there is approximately a 15% wire area penalty, which, according to MINDS analysis, has a negligible impact at the system level.

Results of MINDS analysis, described and shown further in the provisional application (Ser. No. 60/736,075), reveal that use of designs based on the repeater insertion model described herein (e.g., separate Vₜ values for logic transistors and repeaters) reduces power of the logic block by approximately 33%, and further that there is approximately a 5% wire area overhead but no performance penalty.

In light of the above disclosure, it would be appreciated by one having ordinary skill in the art that optimized microchips can be designed and/or fabricated based on the repeater insertion model. Fabrication and/or design of microchips utilizing different parameters as explained above can be implemented in part or in whole through a computer-based system, as described by one exemplary embodiment below.

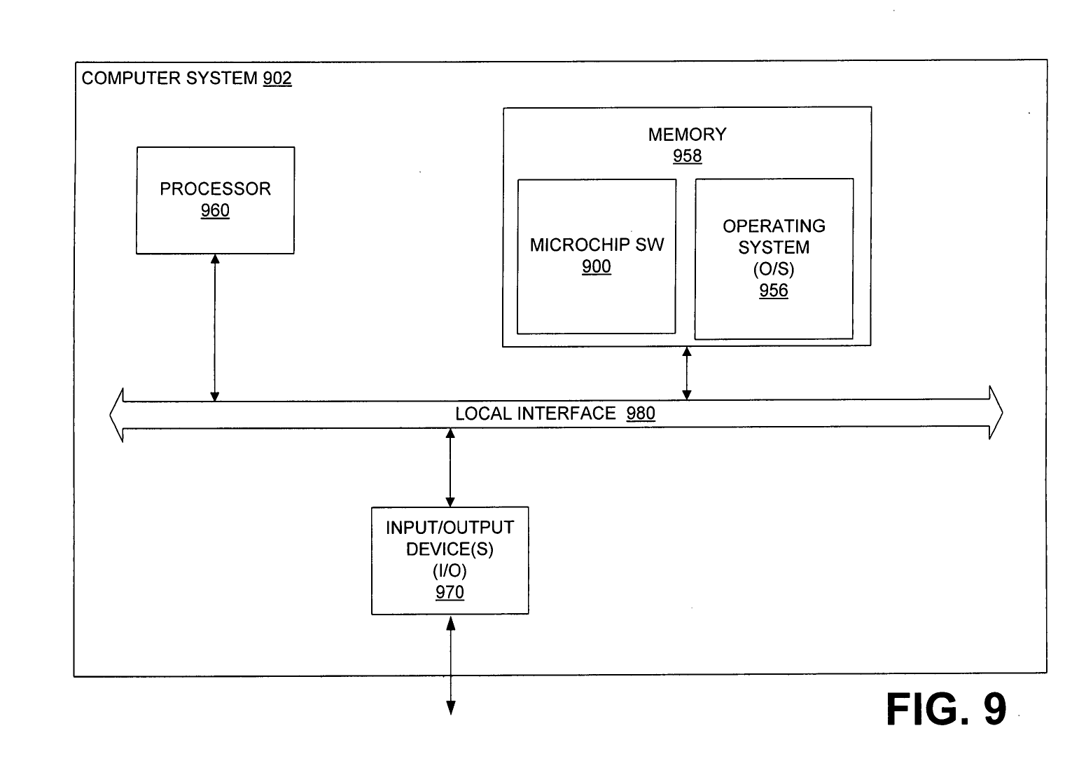

FIG. 9 is a block diagram of an embodiment of a computer system 902 that implements microchip software 900, which is based on the repeater insertion model. In one embodiment, the microchip software 900 may be incorporated in, or used in cooperation with, microchip fabrication software and/or machinery used in the fabrication of an optimized microchip. In some embodiments, the microchip software 900 may be incorporated in, or used in cooperation with, circuit design software, to design an optimized microchip. One skilled in the art will understand that additional components or different components with similar functionality can be included in the computer system 902, and/or some components can be omitted, in some embodiments. In one embodiment, the microchip software 900 can be implemented in software, as an executable program, and can be executed by a special or general purpose digital computer, such as a personal computer (PC; IBM-compatible, Apple-compatible, or otherwise), workstation, minicomputer, or mainframe computer, or fabrication machine.

Generally, in terms of hardware architecture, as shown in FIG. 9, the computer system 902 includes a processor 960, memory 958, and one or more input and/or output (I/O) devices 970 (or peripherals, chip fabrication equipment, etc.) that are communicatively coupled via a local interface 980. The local interface 980 can be, for example, one or more buses or other wired or wireless connections. The local interface 980 may have additional elements (not shown) to enable communications, such as controllers, buffers (caches), drivers, repeaters, and receivers. Further, the local interface 980 may include address, control, and/or data connections to enable appropriate communications among the aforementioned components.

The processor 960 is a hardware device capable of executing software, particularly that stored in memory 958. The processor 960 can be any custom made or commercially available processor, a central processing unit (CPU), an auxiliary processor among several processors associated with the computer system 902, a semiconductor based microprocessor (in the form of a microchip or chip set), a macroprocessor, or generally any device for executing software instructions.

Memory 958 can include any one or combination of volatile memory elements (e.g., random access memory (RAM, such as DRAM, SRAM, SDRAM, etc.)) and nonvolatile memory elements (e.g., ROM, hard drive, tape, CDROM, etc.). Moreover, the memory 958 may incorporate electronic, magnetic, optical, and/or other types of storage media. Note that memory 958 can have a distributed architecture, where various components are situated remotely from one another, but can be accessed by the processor 960.

The I/O devices 970 may include input devices, such as a keyboard, mouse, scanner, microphone, etc. Furthermore, the I/O devices 970 may also include output devices, such as a printer, display, robotics, etc. The I/O devices 970 may further include devices that communicate both inputs and outputs, for instance a modulator/demodulator (modem for accessing another device, system, or network), a radio frequency (RF) or other transceiver, a telephonic interface, a bridge, a router, etc.

When the computer system 902 is in operation, the processor 960 is configured to execute software stored within memory 958, to communicate data to and from memory 958, and to generally control operations of the computer system 902 pursuant to the software. The microchip software 900 and the operating system 956, in whole or in part, but typically the latter, are read by the processor 960, perhaps buffered and then executed.

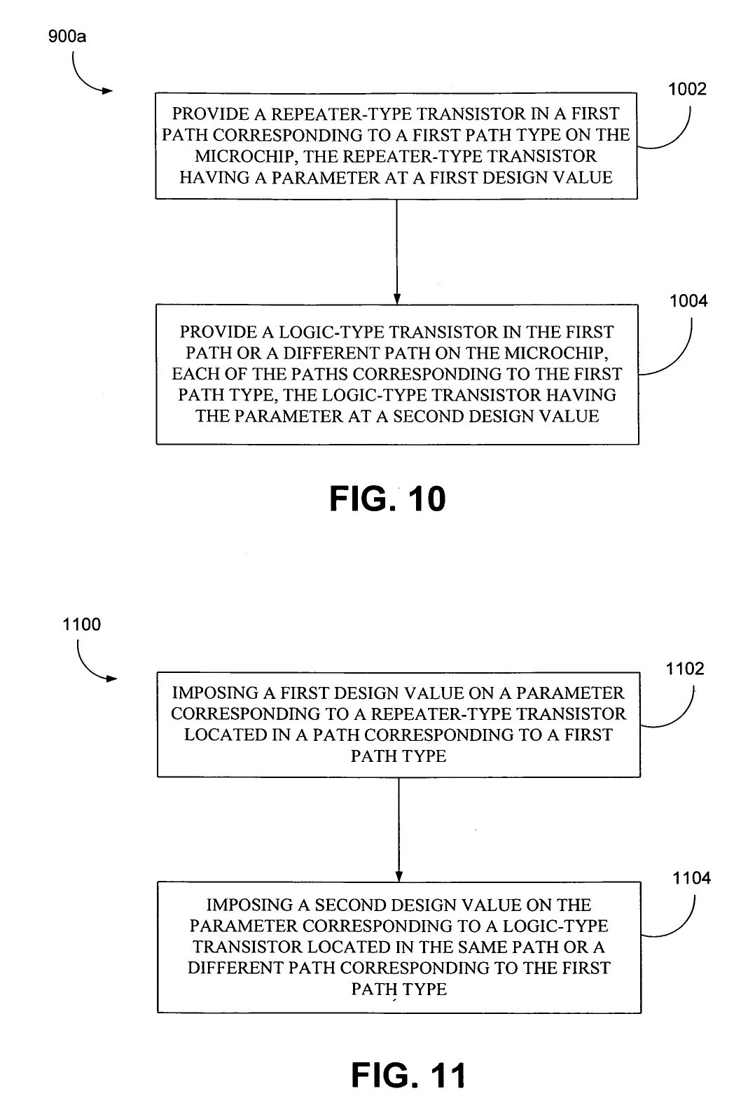

In light of the above disclosure, it would be appreciated that one embodiment of a method of designing or fabricating an optimized microchip, both shown by the method 900a and illustrated in FIG. 10, comprises providing a repeater-type transistor in a first path corresponding to a first path type on the microchip, the repeater-type transistor having a parameter at a first design value (1002), and providing a logic-type transistor in the first path or a different path on the microchip, each of the paths corresponding to the first path type, the logic-type transistor having the parameter at a second design value (1004).

In light of the above disclosure, it would also be appreciated that one embodiment of a method of operating a microchip, as shown by the method 1100 illustrated in FIG. 11, comprises imposing a first design value on a parameter (e.g., providing a predetermined voltage value to terminals or contacts of the microchip) corresponding to a repeater-type transistor located in a path corresponding to a first path type on the microchip (1102), and imposing a second design value on the parameter corresponding to a logic-type transistor located in the same path or a different path corresponding to the first path type on the microchip (1104).

Any process descriptions or blocks in flow diagrams of FIGS. 10 and 11 should be understood as representing acts or modules, segments, or portions of code which include one or more executable instructions for implementing specific logical functions or steps in the process, and alternate implementations are included within the scope of the preferred embodiments in which functions or acts may be executed out of order from that shown or discussed, or may include different, fewer, or greater steps, including substantially concurrently or in reverse order, depending on the functionality involved, as would be understood by those reasonably skilled in the art.

A microchip fabrication, design, or operating method, represented by methods 900a (e.g., fabrication or design method, FIG. 10) and 1100 (e.g., operating method, FIG. 11), which may be implemented using an ordered listing of executable instructions for implementing logical functions, can be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can contain, store, communicate, propagate, or transport the program for use by or in connection with the instruction execution system, apparatus, or device. The computer readable medium can be, for example but not limited to, an electronic, magnetic, optical, electromagnetic, infrared, or semiconductor system, apparatus, device, or propagation medium. More specific examples (a nonexhaustive list) of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM or Flash memory) (electronic), an optical fiber (optical), and a portable compact disc read-only memory (CDROM) (optical). Note that the computer-readable medium could even be paper or another suitable medium upon which the program is printed, as the program can be electronically captured, via for instance optical scanning of the paper or other medium, then compiled, interpreted or otherwise processed in a suitable manner if necessary, and then stored in a computer memory. In addition, the scope of the present disclosure includes embodying the functionality of the preferred embodiments in logic embodied in hardware or software-configured mediums.

It should be emphasized that the above-described embodiments, particularly, any “preferred” embodiments, are merely possible examples of implementations, merely set forth for a clear understanding of the aforementioned principles of an optimized microchip and related methods. Many variations and modifications may be made to the above-described embodiment(s). All such modifications and variations are intended to be included herein within the scope of this disclosure and protected by the following claims.

What is claimed:

1. An optimized microchip method, comprising:
providing a repeater-type transistor in a first path corresponding to a first path type on the microchip, the repeater-type transistor having a parameter at a first design value; and
providing a logic-type transistor in the first path or a different path on the microchip, each of the paths corresponding to the first path type, the logic-type transistor having the parameter at a second design value.

2. The method of claim 1, wherein the first path type comprises a critical path.

3. The method of claim 1, wherein the first path type comprises a non-critical path.

4. The method of claim 1, wherein providing the repeater-type transistor and the logic-type transistor comprises providing the repeater-type transistor having a threshold voltage parameter at the first design value and providing the logic-type transistor having the threshold voltage parameter at the second design value.

5. The method of claim 1, wherein providing the repeater-type transistor and the logic-type transistor comprises providing the repeater-type transistor having a channel length parameter at the first design value and providing the logic-type transistor having the channel length parameter at the second design value.

6. The method of claim 1, wherein providing the repeater-type transistor and the logic-type transistor comprises providing the repeater-type transistor having a gate dielectric thickness parameter at the first design value and providing the logic-type transistor having the gate dielectric thickness parameter at the second design value.

7. The method of claim 1, wherein providing the repeater-type transistor and the logic-type transistor comprises providing the repeater-type transistor having a supply voltage parameter at the first design value and providing the logic-type transistor having the supply voltage parameter at the second design value.

8. The method of claim 1, wherein providing the repeater-type transistor and the logic-type transistor comprises providing a plurality of repeater-type transistors and logic-type transistors.

9. The method of claim 1, wherein the method corresponds to fabricating a microchip.

10. The method of claim 1, wherein the method corresponds to designing a microchip.

11. A microchip, comprising:
a repeater-type transistor located in a first path corresponding to a first path type, the repeater-type transistor having a parameter at a first design value; and
a logic-type transistor located in the first path or a different path, each of the paths corresponding to the first path type, the logic-type transistor having the parameter at a second design value.

12. The microchip of claim 11, wherein the parameter comprises threshold voltage.

13. The microchip of claim 11, wherein the parameter comprises channel length.

14. The microchip of claim 11, wherein the parameter comprises gate dielectric thickness.

15. The microchip of claim 11, wherein the parameter comprises supply voltage.

16. The microchip of claim 11, wherein the path type comprises a critical path.

17. The microchip of claim 11, wherein the path type comprises a non-critical path.

18. A method of operating a microchip, comprising:
imposing a first design value on a parameter corresponding to a repeater-type transistor located in a path corresponding to a first path type; and
imposing a second design value on the parameter corresponding to a logic-type transistor located at the same path or a different path corresponding to the first path type.

19. The method of claim 18, wherein the first path type comprises one of a critical path and a non-critical path.

20. The method of claim 18, wherein the parameter comprises one or more of threshold voltage, channel length, gate dielectric thickness, and supply voltage.

21. A computer readable medium having a computer program implementing an optimized microchip method, the program comprising:
logic configured to provide a repeater-type transistor in a first path corresponding to a first path type on the microchip, the repeater-type transistor having a parameter at a first design value; and
logic configured to provide a logic-type transistor in the first path or a different path on the microchip, each of the paths corresponding to the first path type, the logic-type transistor having the parameter at a second design value.
